(19) United States
(12) Patent Application Publication
(10) Pub. No.: US 2013/0174903 A1
(43) Pub. Date: Jul. 11, 2013

(54) SOLAR CELL

(71) Applicant: INDUSTRIAL TECHNOLOGY RESEARCH INSTITUTE, Hsinchu (TW)

(72) Inventors: Der Chin WU, Tainan City (TW); Jui-Chung SHIAO, New Taipei City (TW); Wei-Chih HSU, Hsinchu County (TW); Chien-Hsun CHEN, Tainan City (TW)

(73) Assignee: INDUSTRIAL TECHNOLOGY RESEARCH INSTITUTE, Hsinchu (TW)

(21) Appl. No.: 13/781,653

(22) Filed: Feb. 28, 2013

Related U.S. Application Data
(62) Division of application No. 13/179,448, filed on Jul. 8, 2011.

(30) Foreign Application Priority Data
Dec. 1, 2010 (TW) 099141649

(51) Int. Cl. H01L 31/072

(52) U.S. Cl. CPC H01L 31/072
USPC 136/256

(57) ABSTRACT

A solar cell is disclosed. A substrate includes a first surface and a second surface, wherein the substrate is of a first type. A through hole passes through the substrate, wherein the substrate includes a third surface in the through hole. An insulating layer is on the third surface in the through hole and extends to be over the second surface of the substrate. A first thin film semiconductor layer is disposed on the first surface of the substrate, wherein the first thin film semiconductor layer is of a first type. A transparent conductive layer is on the first thin film semiconductor layer. A through hole connection layer is disposed in the through hole and extends to be over the first surface and the second surface of the substrate.

### CROSS REFERENCE TO RELATED APPLICATIONS

This application is a Divisional application of pending U.S. patent application Ser. No. 13/179,448, filed Jul. 8, 2011 and entitled “SOLAR CELL”, which claims priority of Taiwan Patent Application No. 99141649, filed on Dec. 1, 2010, the entirety of which are incorporated by reference herein.

### BACKGROUND

1. Technical Field

The invention relates in general to a solar cell, and more particularly to a back-contact hetero junction solar cell.

2. Description of the Related Art

A silicon wafer is formed using mature technology and silicon material is widely used in the semiconductor industry. Especifically, silicon materials have energy gaps which are suitable for absorbing sunlight. Therefore, silicon wafers are widely used as the solar cell devices.

Back-contact solar cells use through holes in chips to direct bus bars at the front side to the back side. This technique can not only increase a front-side illumination area to increase cell efficiency, but can also reduce gaps between cells to increase efficiency of back electrode modules.

Hetero junction solar cells grow amorphous silicon passivation layers and amorphous silicon emitters on a silicon chip, so that the solar cells can have ultra low recombination velocity. Therefore, hetero junction solar cells have high open circuit voltages (more than 0.7V) and high conversion efficiency.

### SUMMARY

The invention provides a solar cell, comprising the following elements. A substrate comprises a first surface and a second surface, wherein the substrate is of a first type. A through hole passes through the substrate, wherein the substrate comprises a third surface in the through hole. A first thin film semiconductor layer is disposed on the third surface in the through hole and extended to be over the second surface of the substrate, wherein the first thin film semiconductor layer is second type. A second thin film semiconductor layer is disposed on the first surface of the substrate. A through hole connection layer is disposed in the through hole and extended to be over the first surface and the second surface of the substrate, wherein a junction is formed between the first thin film semiconductor layer and the substrate to prevent shorts from occurring between the through hole connection layer and the substrate.

The invention further provides another solar cell, comprising the following elements. A substrate comprises a first surface and a second surface, wherein the substrate is of a first type. A through hole passes through the substrate, wherein the substrate comprises a third surface in the through hole. An insulating layer is disposed on the third surface in the through hole and extended to be over the second surface of the substrate. A first thin film semiconductor layer is disposed on the first surface of the substrate, wherein the first thin film semiconductor layer is of a first type. A transparent conductive layer is disposed on the first thin film semiconductor layer. A through hole connection layer is disposed in the through hole and extended to be over the first surface and the second surface of the substrate.

### BRIEF DESCRIPTION OF DRAWINGS

The invention can be more fully understood by reading the subsequent detailed description and examples with references made to the accompanying drawings, wherein,

FIG. 1A˜FIG. 1H show cross sections of the stages of a method for forming a metal wrap-through back contact electrode solar cell with single side hetero junction of an embodiment of the invention.

FIG. 2A˜FIG. 2J show cross sections of the stages of a method for forming a metal wrap-through back contact electrode solar cell with double side hetero junctions of an embodiment of the invention.

FIG. 3A˜FIG. 3F show cross sections of the stages of a method for forming a metal wrap-through back contact electrode solar cell with single side hetero junction of an embodiment of the invention.

FIG. 4A˜FIG. 4F show cross sections of the stages of a method for forming a metal wrap-through back contact electrode solar cell with double side hetero junctions of an embodiment of the invention.

FIG. 5A˜FIG. 5G show cross sections of the stages of a method for forming a metal wrap-through back contact electrode solar cell with double side hetero junctions of an embodiment of the invention.

FIG. 6 shows short current (Jsc) and power as a function of voltage of a metal wrap-through back contact electrode solar cell with double side hetero junctions of the example shown in FIG. 2J.

FIG. 7 shows short current (Jsc) and power as a function of voltage of a metal wrap-through back contact electrode solar cell with double side hetero junctions of the example shown in FIG. 4F.

### DETAILED DESCRIPTION OF DISCLOSURE

Embodiments of the invention are illustrated in the following paragraph. The embodiments are used to describe characteristics of the invention but do not limit the invention.

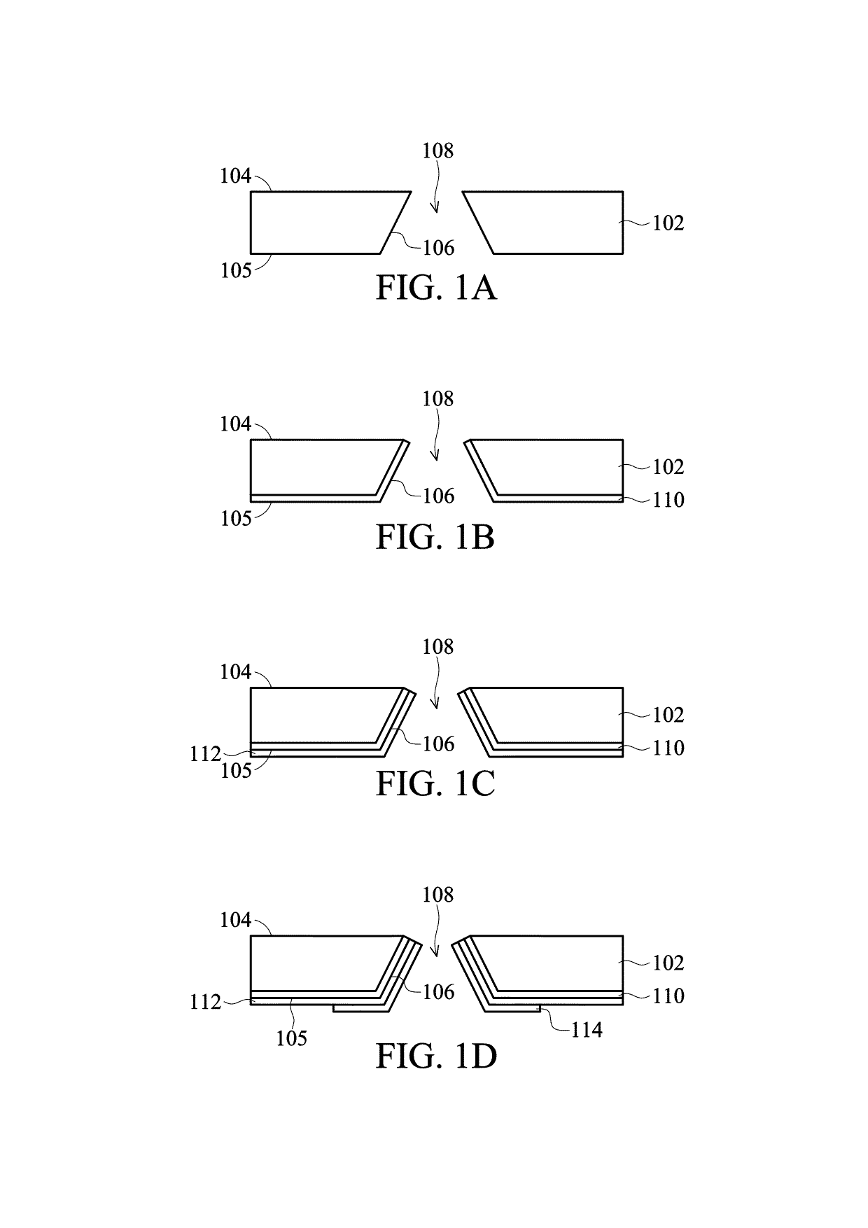

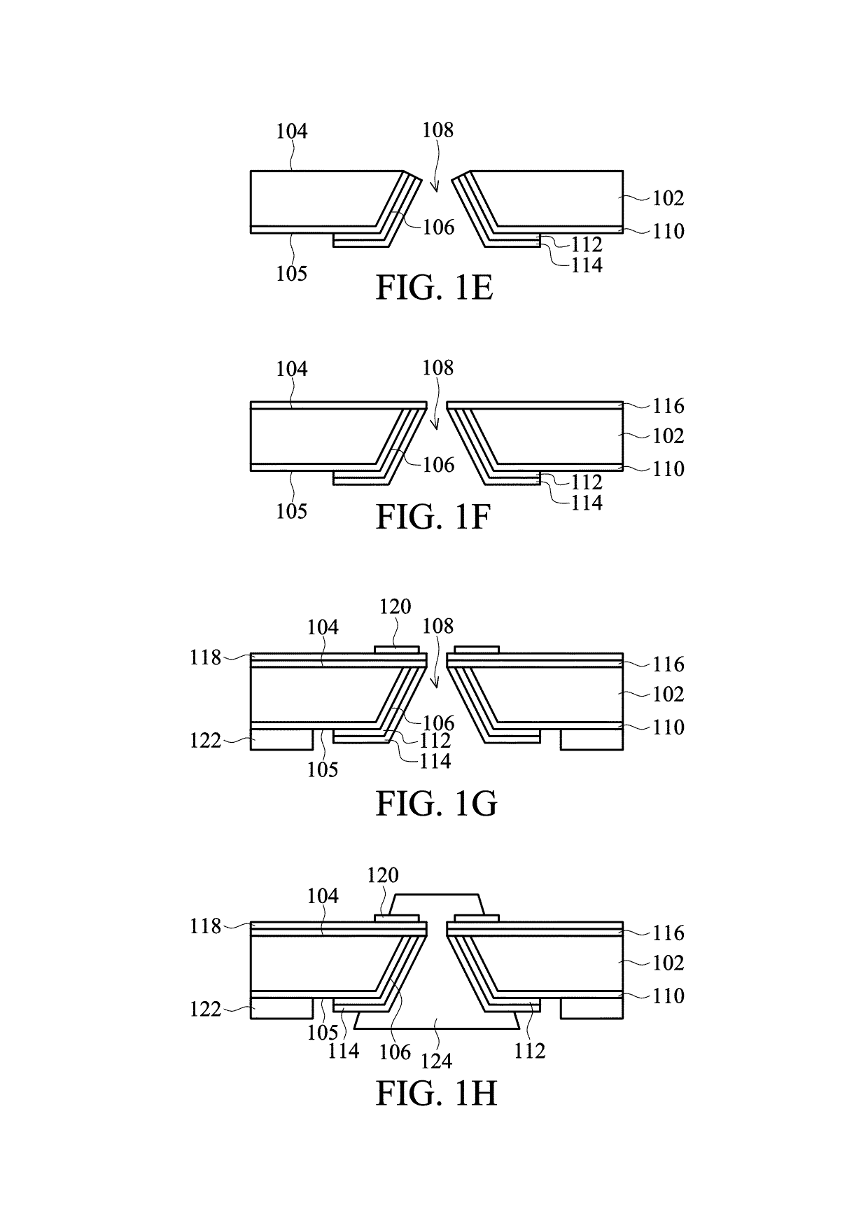

A method for forming a metal wrap-through back contact electrode solar cell with single side hetero junction is illustrated with FIG. 1A˜FIG. 1H. Referring to FIG. 1A, a substrate 102 comprising a first surface 104 and a second surface 105 is provided. The substrate 102 can be formed with single crystalline silicon, or multi-crystalline silicon or other suitable semiconductor materials. Next, a drilling step is performed to the substrate 102 to form a through hole 108 in the substrate 102. Note that the surface in the through hole 108 is referred to as a third surface 106 in the following paragraph. A method for forming the through hole of an embodiment of the invention comprises HF/HNO₃ acid etching, KOH or NaOH alkali etching, drying etching (for example using Cl₂, Cf₄, BCl₃ as etching gases) or laser removing (for example Nd:YAG laser, semiconductor laser, Q-Switch laser, laser with gas of XeCl₃, KrF or ArF, or other related laser with energy higher than 1 J/cm²). In a preferred embodiment of the invention, laser is used to drill the substrate 102 to form through holes 108. In an embodiment of the invention, the substrate 102 is a first type semiconductor, such as an n type. Referring to FIG. 1B, a doping process is performed to form a doping region 110 under the second surface 105 of the substrate 102 and the third surface 106 in the through hole 108 of the substrate 102. In an embodiment of the invention, the doping process described is a thermal diffusing process, the doping region 110 is of a first type, such as an n type, and the doping source is POCl₃. Thereafter, referring to FIG. 1C, a first thin film semiconductor layer 112 is formed on doping region 110 and on the second surface 105 of the substrate 102 and the third surface 106 in the through hole 108 of the substrate 102. In general, a thin film semiconductor layer comprises amorphous silicon, nanocrystalline silicon, microcrystalline silicon, microcrystalline silicon carbonate, amorphous silicon germanium, nanocrystalline silicon germanium, microcrystalline silicon germanium, amorphous germanium, nanocrystalline germanium, or microcrystalline germanium. In an embodiment of the invention, the thin film semiconductor layer is an amorphous silicon layer. In an embodiment of the invention, the first thin film semiconductor layer 112 is a second type amorphous silicon layer, such as a p type, and an intrinsic thin film semiconductor layer (not shown) can be inserted between the first thin film semiconductor layer 112 and the doping region 110. The method for forming the amorphous silicon can be plasma enhanced chemical vapor deposition, sputtering, etc. The p-type amorphous silicon can be formed with silane, hydrogen gas and B₂H₆ introduced into a plasma enhanced chemical vapor deposition system. Typically, the other elements of group III, such as aluminum, of gallium can be used as p type doping elements. The n-type amorphous silicon can be formed with silane, hydrogen gas and PH₃ introduced into a plasma enhanced chemical vapor deposition system. The other elements of group V, such as arsenic can be used as n type doping elements. The intrinsic amorphous silicon of the embodiment can be formed with silane and hydrogen gas introduced into a plasma enhanced chemical vapor deposition system. Referring to FIG. 1D, a first patterned metal layer 114 is formed on the first thin film semiconductor layer 112 overlying the second surface 105 of the substrate 102 and the third surface 106 in the through hole 108 of the substrate 102 by a process, such as a screen-printing, sputtering, evaporation or plating process. In an embodiment of the invention, the first patterned metal layer 114 is formed of a high-conductivity metal, such as aluminum or silver. Referring to FIG. 1E, a chemical etching process is performed using the first patterned metal layer 114 as a mask to remove the first thin film semiconductor layer 112 not covered by the first patterned metal layer 114. Referring to FIG. 1F, a second thin film semiconductor layer 116 is formed on the first surface 104 of the substrate 102 to act as an emitter. In an embodiment of the invention, the second thin film semiconductor layer 116 is a second-type amorphous silicon, such as p type. An intrinsic thin film semiconductor layer (not shown) can be inserted between the second thin film semiconductor layer 116 and the substrate 102. Referring to FIG. 1G, a transparent conductive layer 118 is formed on the second thin film semiconductor layer 116. In an embodiment of the invention, the transparent conductive layer 118 comprises indium tin oxide (ITO). In general, the transparent conductive material can be metal oxide, such as an indium oxide series, tin oxide series, zinc oxide series, etc. Next, a second patterned metal layer 120 is formed on the transparent conductive layer 118 by, for example, a screen printing process, and a third patterned metal layer 122 is formed on the second surface 105 of the substrate 102. In an example of the invention, the second patterned metal layer 120 and the third patterned metal layer 122 are formed of metal with a high conductive coefficient, such as aluminum or silver. Thereafter, referring to FIG. 1H, a through hole connection layer 124 is formed, for example, by a screen printing process, to electrically connect the patterned metal layer over the first surface 104 and the second surface 105 of the substrate 102 for directing the bus bar on the front side of the substrate 102 to the back side.

According to the description above, a metal wrap-through back contact electrode solar cell with single side hetero junction comprises the following elements. A first type substrate 102 comprises a first surface 104 and a second surface 105. A through hole 108 passes through the substrate 102, wherein the through hole 108 in the substrate 102 comprises a third surface 106. A first thin film semiconductor layer 112 is disposed on the third surface 106 in the through hole 108 and extended to be over the second surface 105 of the substrate 102, wherein the first thin film semiconductor layer 112 is a second type amorphous silicon layer. A doping region 110 is disposed below the second surface 105 of the substrate 102 and the third surface 106 in the through hole 108, wherein the doping region 110 is of a first type. A second thin film semiconductor layer 116 is disposed on the first surface 104 of the substrate 102. A transparent conductive layer 118 is disposed on the second thin film semiconductor layer 116. A first patterned metal layer 114 is disposed in the through hole 108, a second patterned metal layer 120 is disposed on the transparent conductive layer 118, and a third patterned metal layer 122 is disposed on the second surface 105 of the substrate 102. A through hole connection layer 124 is disposed in the through hole 108 and extended to be over the first surface 104 and the second surface 105 of the substrate 102, wherein a junction is formed between the first thin film semiconductor layer 112 and the substrate 102 to prevent short there between.

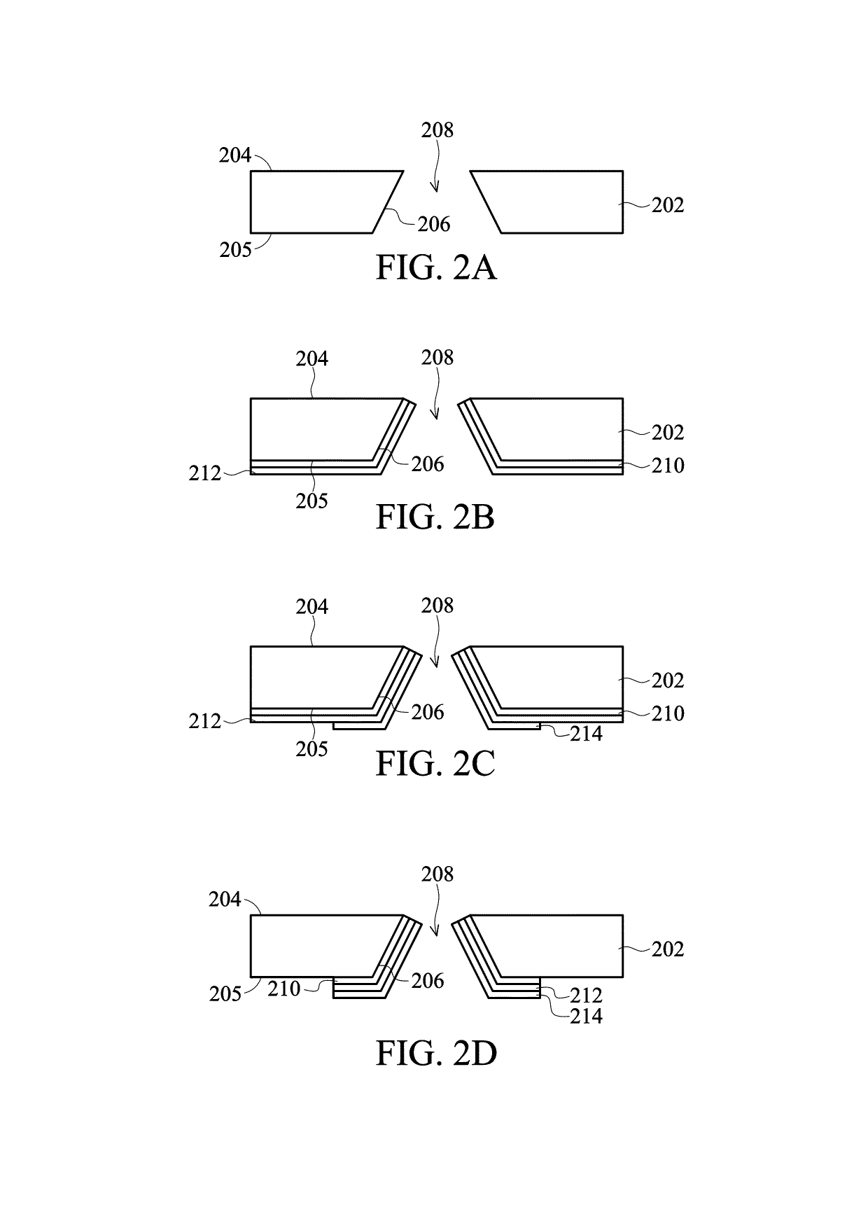

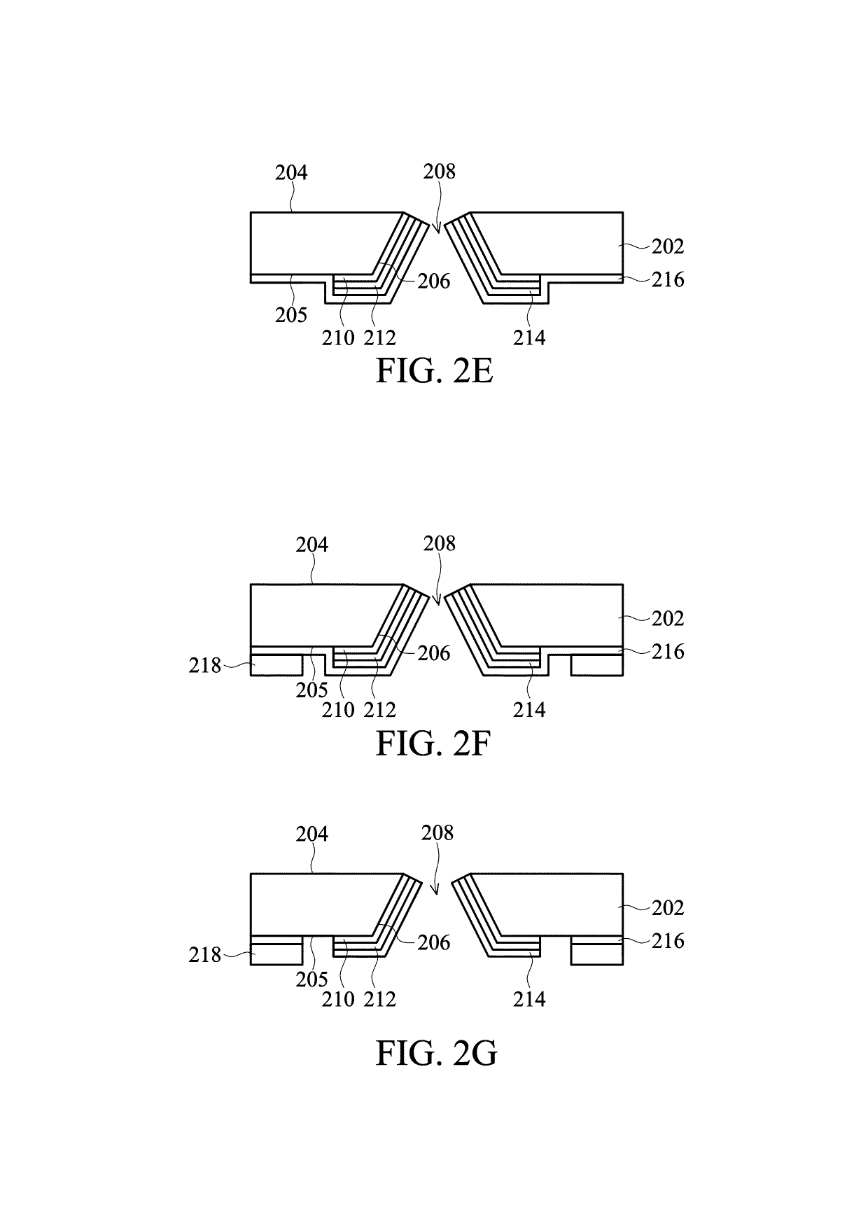

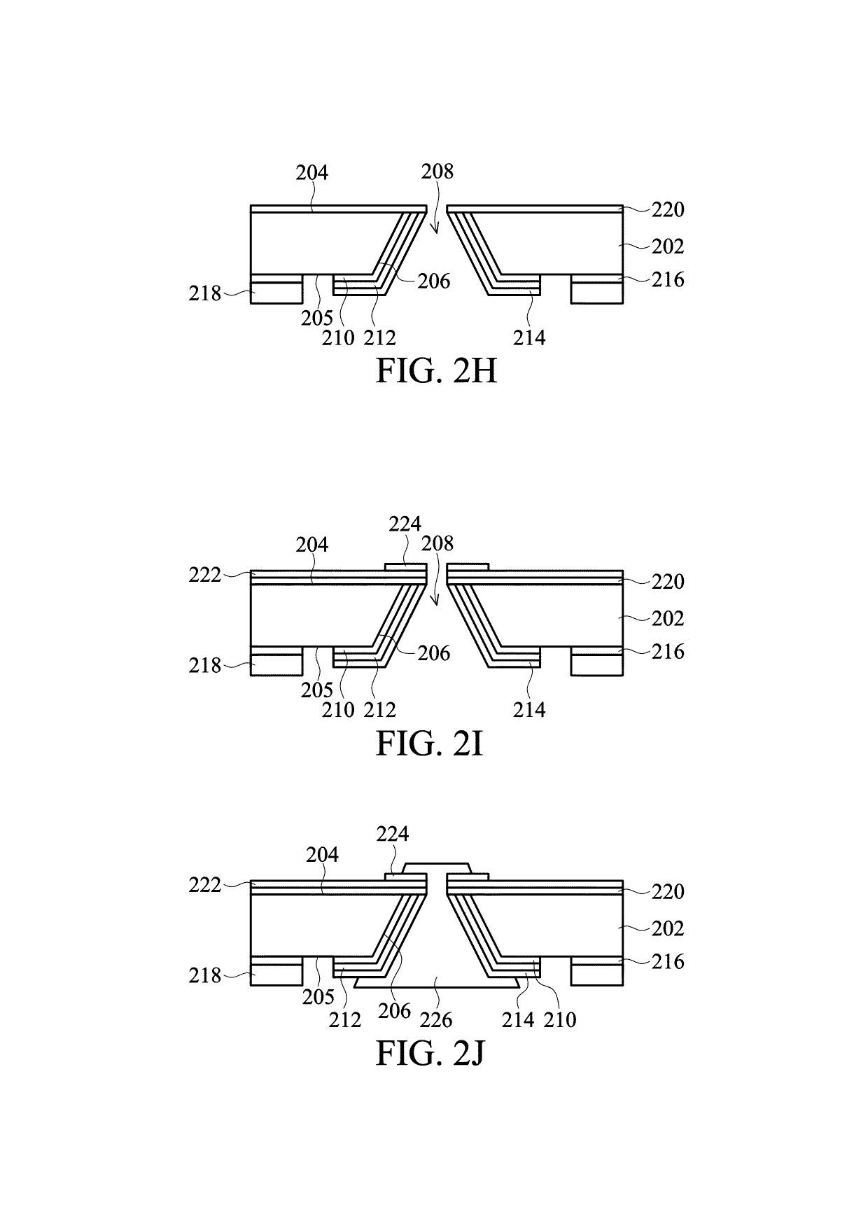

A method for forming a metal wrap-through back contact electrode solar cell with double side hetero junctions is illustrated with FIG. 2A˜FIG. 2J. Referring to FIG. 2A, a substrate 202 comprising a first surface 204 and a second surface 205 is provided. The substrate 202 can be formed with single crystalline silicon, or multi-crystalline silicon or other suitable semiconductor materials. Next, a drilling step is performed to the substrate 202 to form a through hole 208 in the substrate 202. Note that the surface in the through hole 208 is referred to as a third surface 206 in the following paragraph. In an embodiment of the invention, the substrate 202 is a first type semiconductor, such as an n type. Referring to FIG. 2B, a first thin film semiconductor layer 210 and a second thin film semiconductor layer 212 are formed on the second surface 205 of the substrate 202 and the third surface 206 in the through hole 208. In general, the thin film semiconductor layer comprises amorphous silicon, nanocrystalline silicon, microcrystalline silicon, microcrystalline silicon carbonate, amorphous silicon germanium, nanocrystalline silicon germanium, microcrystalline silicon germanium, amorphous germanium, nanocrystalline germanium, or microcrystalline germanium. In an embodiment of the invention, the first thin film semiconductor layer 210 is an intrinsic amorphous silicon, the second thin film semiconductor layer 212 is a second type amorphous silicon layer, such as a p type. Referring to FIG. 2C, a first patterned metal layer 214 is formed on the second surface 205 of the substrate 202 and on the second thin film semiconductor layer 212 in the through hole 208 on the third surface 206 of the substrate 202 by a process, such as a screen-printing, sputtering, evaporation or plating process. In an embodiment of the invention, the first patterned metal layer 214 is formed of a high-conductivity metal, such as aluminum or silver. Referring to FIG. 2D, a chemical etching process is performed using the first patterned metal layer 214 as a mask to remove the first thin film semiconductor layer 210 and the second thin film semiconductor layer 212 not covered by the first patterned metal layer 214. Referring to FIG. 2E, a third thin film semiconductor layer 216 is formed on the second surface 205 of the substrate 202 and over the third surface 206 in the trough hole 208 of the substrate 202. In an embodiment of the invention, the third thin film semiconductor layer 216 is a first-type amorphous silicon, such as an n type. An intrinsic thin film semiconductor layer (not shown) can be inserted between the third thin film semiconductor layer 216 and the substrate 202. Next, a second patterned metal layer 218 is formed on the third thin film semiconductor layer 216 by, for example, a screen printing process. In an embodiment of the invention, the second patterned metal layer 218 is an electrode formed of metal with a high conductive coefficient, such as aluminum or silver. A transparent conductive layer (not shown) can be inserted between the third thin film semiconductor layer 216 and the patterned metal layer 218. Referring to FIG. 2G, a chemical etching process is performed using the second patterned metal layer 218 as a mask to remove the third thin film semiconductor layer 216 uncovered by the second patterned metal layer 218. Referring to FIG. 2H, a fourth thin film semiconductor layer 220 is formed on the first surface 204 of the substrate 202 to act as an emitter. In an embodiment of the invention, the fourth thin film semiconductor layer 220 is an amorphous silicon of a second type, such as a p type. An intrinsic thin film semiconductor layer (not shown) can be inserted between the fourth thin film semiconductor layer 220 and the substrate 202. Referring to FIG. 2I, a transparent conductive layer 222 is formed on the fourth thin film semiconductor layer 220. In an embodiment of the invention, the transparent conductive layer 222 is an indium tin oxide (ITO). Next, a third patterned metal layer 224 is formed on the transparent conductive layer 222 by, for example, a screen printing process. In an embodiment of the invention, the third patterned metal layer 224 is formed of a high-conductivity metal, such as aluminum or silver. Thereafter, referring to FIG. 2J, a through hole connection layer 226 is formed, for example, by a screen printing process, to electrically connect the patterned metal layers over the first surface 204 and the second surface 205 of the substrate 202 for directing the bus bar on the front side of the substrate 202 to the back side.

According to the description above, a metal wrap-through back contact electrode solar cell with double side hetero junctions comprises the following elements. A substrate 202 comprises a first surface 204 and a second surface 205, wherein the substrate 202 is of a first type. A through hole 208 passes through the substrate 202, wherein the through hole 208 in the substrate 202 comprises a third surface 206. A first thin film semiconductor layer 210 is disposed on the third surface 206 in the through hole 208 and extended to be over the second surface 205 of the substrate 202, wherein the first thin film semiconductor layer 210 is an intrinsic amorphous silicon layer. A second thin film semiconductor layer 212 is disposed on the first thin film semiconductor layer 210, wherein the second thin film semiconductor layer 212 is a second type amorphous silicon layer. A third thin film semiconductor layer 216 is disposed on the second surface 205 of the substrate 202. A second patterned metal layer 218 is disposed on the third thin film semiconductor layer 216. A fourth thin film semiconductor layer 220 is disposed on the first surface 204 of the substrate 202. A transparent conductive layer 222 is disposed on the fourth thin film semiconductor layer 220. A third patterned metal layer 224 is disposed on the transparent conductive layer 222. A through hole connection layer 226 is disposed in the through hole 208 and extended to be over the first surface 204 and the second surface 205 of the substrate 202, wherein a junction is formed between the second thin film semiconductor layer 212 to prevent a short of the metal layer in the through layer, which would generate a short of the substrate 202.

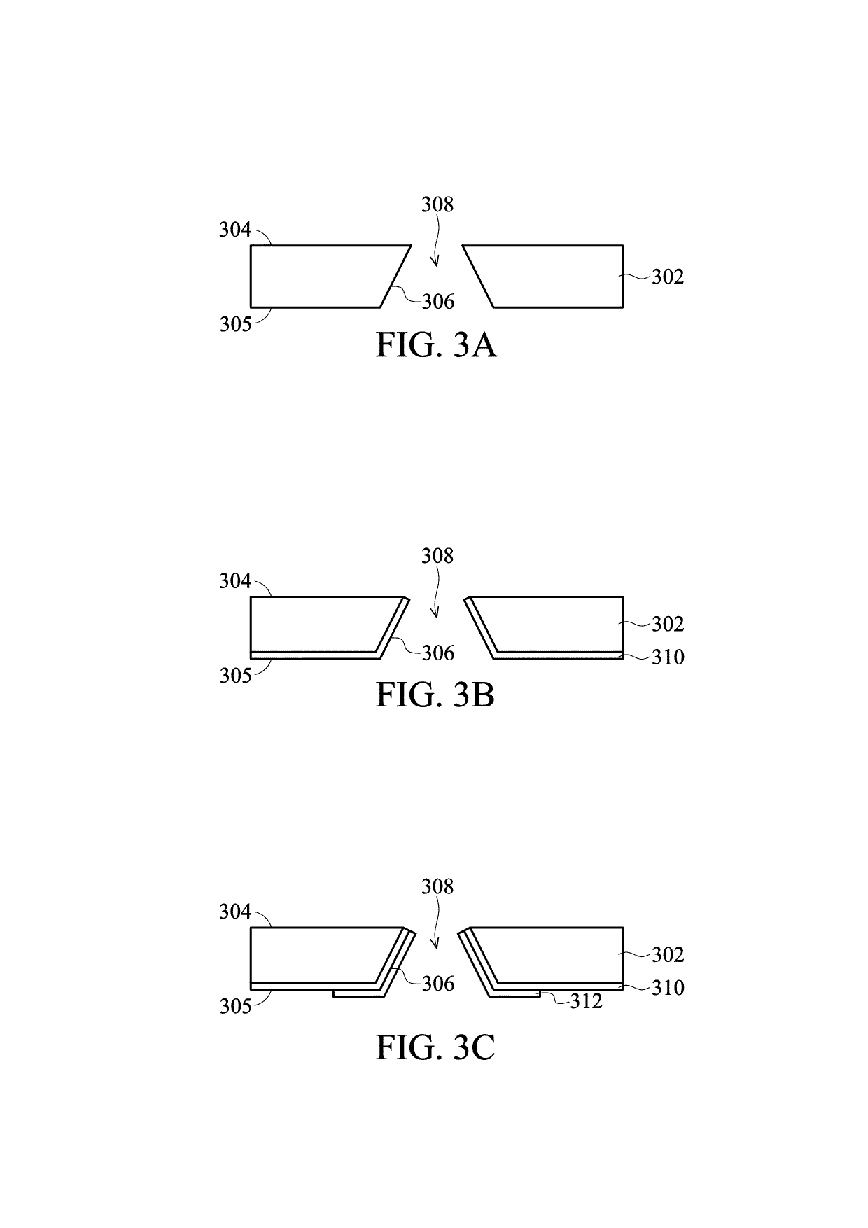

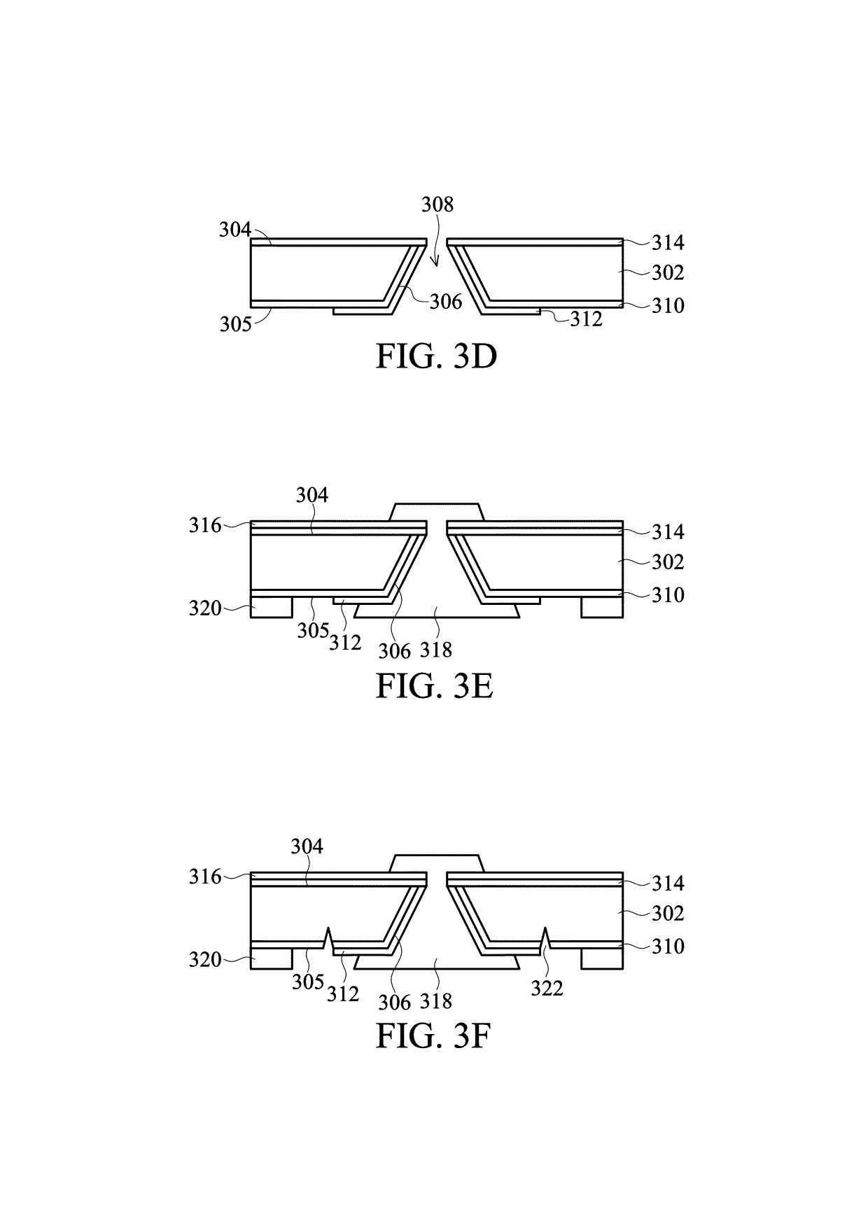

A method for forming a metal wrap-through back contact electrode solar cell with single side hetero junctions is illustrated with FIG. 3A˜FIG. 3F. Referring to FIG. 3A, a substrate 302 comprising a first surface 304 and a second surface 305 is provided. The substrate 302 can be formed with single crystalline silicon, or multi-crystalline silicon or other suitable semiconductor materials. Next, a drilling step is performed to the substrate 302 to form a through hole 308 in the substrate 302. Note that the surface in the through hole 308 is referred to as a third surface 306 in the following paragraph. In an embodiment of the invention, the substrate 302 is a first type semiconductor, such as an n type. Referring to FIG. 3B, a doping process is performed to form a doping region 310 under the second surface 305 of the substrate 302 and the third surface 306 in the through hole 308 of the substrate 302. In an embodiment of the invention, the doping process described is a thermal diffusing process, the doping region 310 is of a first type, such as an n type, and the doping source is POCl₃. Thereafter, an insulating layer 312 is formed on the doping region 310 and on the second surface 305 of the substrate 302 and the third surface 306 in the through hole 308 of the substrate 302. In an embodiment of the invention, the insulating layer 312 is formed of insulating material, such as silicon oxide, aluminum oxide, polymer and other non-conductive materials. Referring to FIG. 3D, a first thin-film semiconductor layer 314 is formed on the first surface 304 of the substrate 302 to act as an emitter. In general, a thin film semiconductor layer comprises amorphous silicon, nanocrystalline silicon, microcrystalline silicon, microcrystalline silicon carbonate, amorphous silicon germanium, nanocrystalline silicon germanium, microcrystalline silicon germanium, amorphous germanium, nanocrystalline germanium, or microcrystalline germanium. In an embodiment of the invention, the thin film semiconductor layer is an amorphous silicon layer. In an embodiment of the invention, the first thin film semiconductor layer 314 is a second type amorphous silicon layer, such as a p type, and an intrinsic thin film semiconductor layer (not shown) can be inserted between the first thin film semiconductor layer 314 and the substrate 302. Referring to FIG. 3E, a transparent conductive layer 316 is formed on the first thin semiconductor layer 314. In an embodiment of the invention, the transparent conductive layer 316 can be indium tin oxide (ITO). Next, a patterned metal layer 320 is formed on the second surface 305 of the substrate 302 by, for example, a screen printing process. In an embodiment of the invention, the patterned metal layer 320 is formed of metal with a high conductive coefficient, such as aluminum or silver. Thereafter, a through hole connection layer 318 is formed, for example, by a screen printing process, to electrically connect the patterned metal layer 320 over the first surface 304 and the second surface 305 of the substrate 302 for directing the bus bar on the front side of the substrate 302 to the back side. Next, referring to FIG. 3F, the second surface 305 of the substrate 302 is cut by a laser to provide isolation and decrease leakage.

According to the description above, a metal wrap-through back contact electrode solar cell with single side hetero junctions comprises the following elements. A substrate 302 comprising a first surface 304 and a second surface 305 is provided, wherein the substrate 302 is of a first type. A through hole 308 passes through the substrate 302, wherein the through hole 308 in the substrate 302 comprises a third surface 306. A doping region 310 is disposed below the second surface 305 of the substrate 302 and the third surface 306 in the through hole 308, wherein the doping region 310 is of a first type. An insulating layer 312 is disposed on the third surface 306 in the through hole 308 and extended to be over the second surface 305 of the substrate 302. A first thin film semiconductor layer 314 is disposed on the first surface 304 of the substrate 302. A transparent conductive layer 316 is disposed on the first thin film semiconductor layer 314. A patterned metal layer 320 is disposed on the second surface 305 of the substrate 302. A through hole connection layer 318 is disposed in the through hole 308 and extended to be over the first surface 304 and the second surface 305 of the substrate 302.

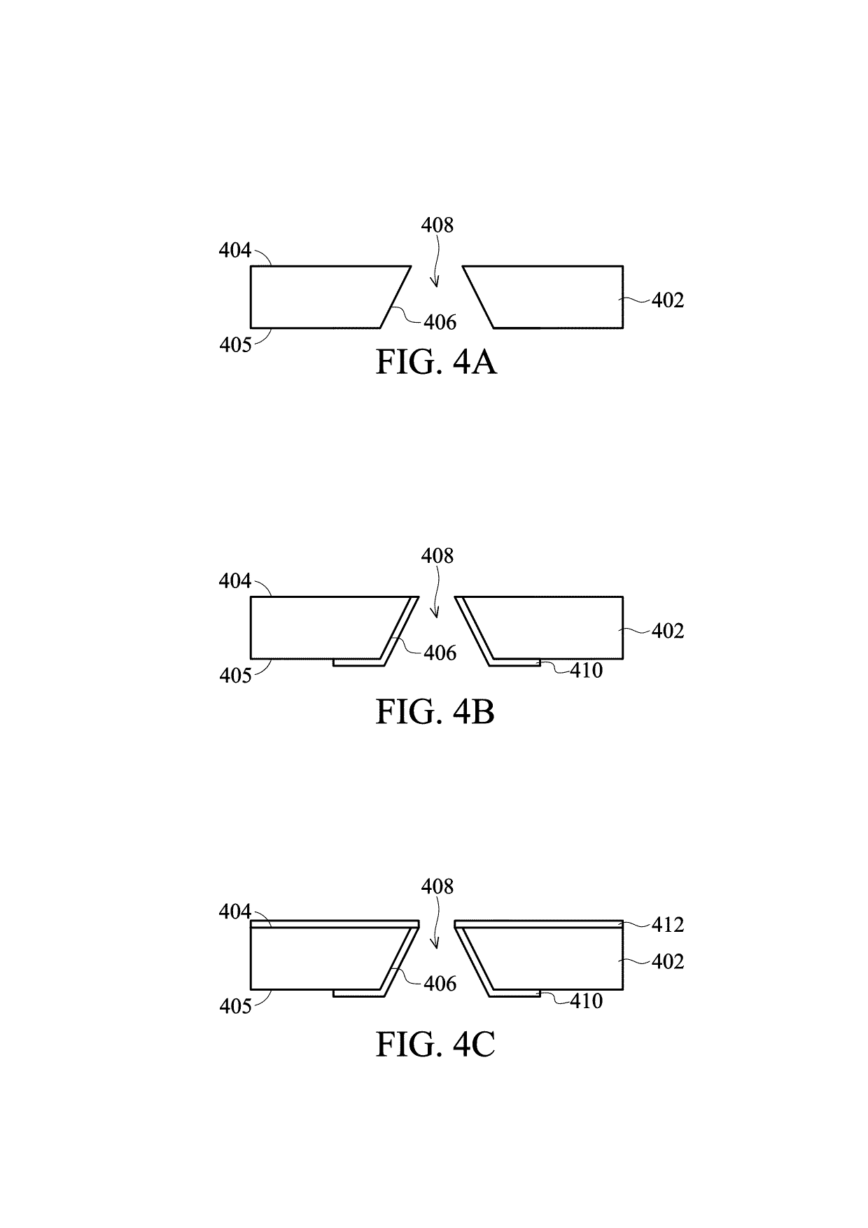

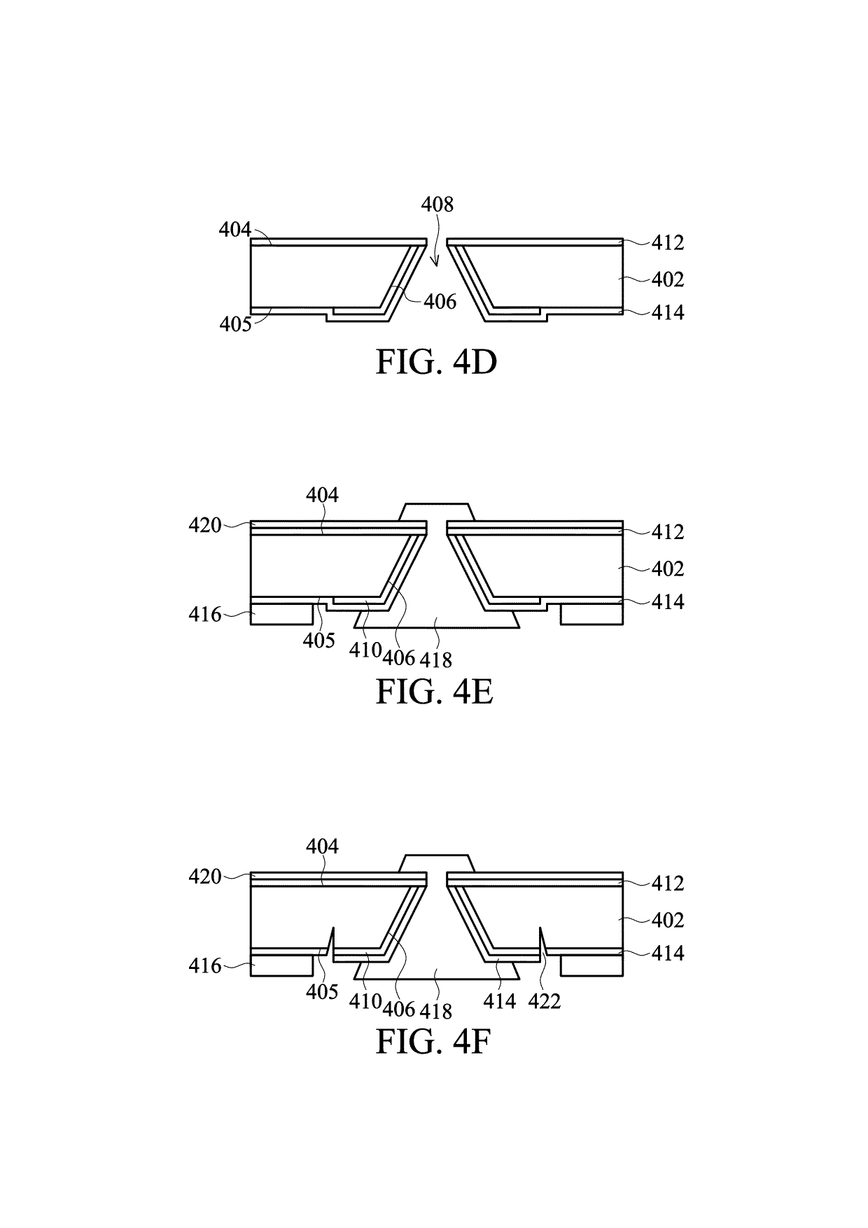

A method for forming a metal wrap-through back contact electrode solar cell with double side hetero junctions is illustrated with FIG. 4A˜FIG. 4F. Referring to FIG. 4A, a substrate 402 comprising a first surface 404 and a second surface 405 is provided. The substrate 402 can be formed with single crystalline silicon, or multi-crystalline silicon or other suitable semiconductor materials. Next, a drilling step is performed to the substrate 402 to form a through hole 408 in the substrate 402. Note that the surface in the through hole 408 is referred to as a third surface 406 in the following paragraph. In an embodiment of the invention, the substrate 402 is a first type semiconductor, such as an n type. Referring to FIG. 4B, a insulating layer 410 is formed on the second surface 405 of the substrate 402 and the third surface 406 in the through hole 408. In an embodiment of the invention, the insulating layer 410 comprises silicon nitride. Referring to FIG. 4C, a first thin film semiconductor layer 412 is formed on the first surface 404 of the substrate 402 to act as an emitter. In general, the thin film semiconductor layer comprises amorphous silicon, nanocrystalline silicon, microcrystalline silicon, microcrystalline silicon carbonate, amorphous silicon germanium, nanocrystalline silicon germanium, microcrystalline silicon germanium, amorphous germanium, nanocrystalline germanium, or microcrystalline germanium. In an embodiment of the invention, the first thin film semiconductor layer 412 is a second type amorphous silicon layer, such as a p type. An intrinsic thin film semiconductor layer (not shown) can be disposed between the first thin film semiconductor layer 412 and the substrate 402. Next, referring to FIG. 4D, a second thin film semiconductor layer 414 is formed on the second surface 405 of the substrate 402 and extended to be over the insulating layer 410 in the through hole 408. In an embodiment of the invention, the second thin film semiconductor layer 414 is a first type amorphous silicon layer, such as an n type. An intrinsic thin film semiconductor layer (not shown) can be disposed between the second thin film semiconductor layer 414 and the substrate 402. Referring to FIG. 4E, a transparent conductive layer 420 is formed on the first thin film semiconductor layer 412. In an embodiment of the invention, the transparent conductive layer 420 comprises indium tin oxide (ITO). Next, a patterned metal layer 416 is formed on the second surface 405 of the substrate 402 by, for example, a screen printing process. In an embodiment of the invention, the patterned metal layer 416 is formed of metal with a high conductive coefficient, such as aluminum or silver. A transparent conductive layer (not shown) can be inserted between the second thin film semiconductor layer 414 and the patterned metal layer 416. Thereafter, a through hole connection layer 418 is formed, for example, by a screen printing process, to electrically connect the patterned metal layer 416 over the first surface 404 and the second surface 405 of the substrate 402 for directing the bus bar on the front side of the substrate 402 to the back side. Next, referring to FIG. 4F, the second surface 405 of the substrate 402 is cut by a laser to form a cut opening 422 for providing isolation and decreasing leakage of the solar cell.

According to the description above, a metal wrap-through back contact electrode solar cell with double side hetero junctions comprises the following elements. A substrate 402 comprising a first surface 404 and a second surface 405 is provided, wherein the substrate 402 is of a first type. A through hole 408 passes through the substrate 402, wherein the through hole 408 in the substrate 402 comprises a third surface 406. An insulating layer 410 is disposed on the third surface 406 in the through hole 408 and extended to be over the second surface 405 of the substrate 402. A first thin film semiconductor layer 412 is disposed on the first surface 404 of the substrate 402. A transparent conductive layer 420 is disposed on the first thin film semiconductor layer 412. A second thin film semiconductor layer 414 is disposed on the second surface 405 of the substrate 402 and extended to be over the insulating layer 410 in the through hole 408. A patterned metal layer 416 is disposed on the second surface 405 of the substrate 402. A through hole connection layer 418 is disposed in the through hole 408 and extended to be over the first surface 404 and the second surface 405 of the substrate 402.

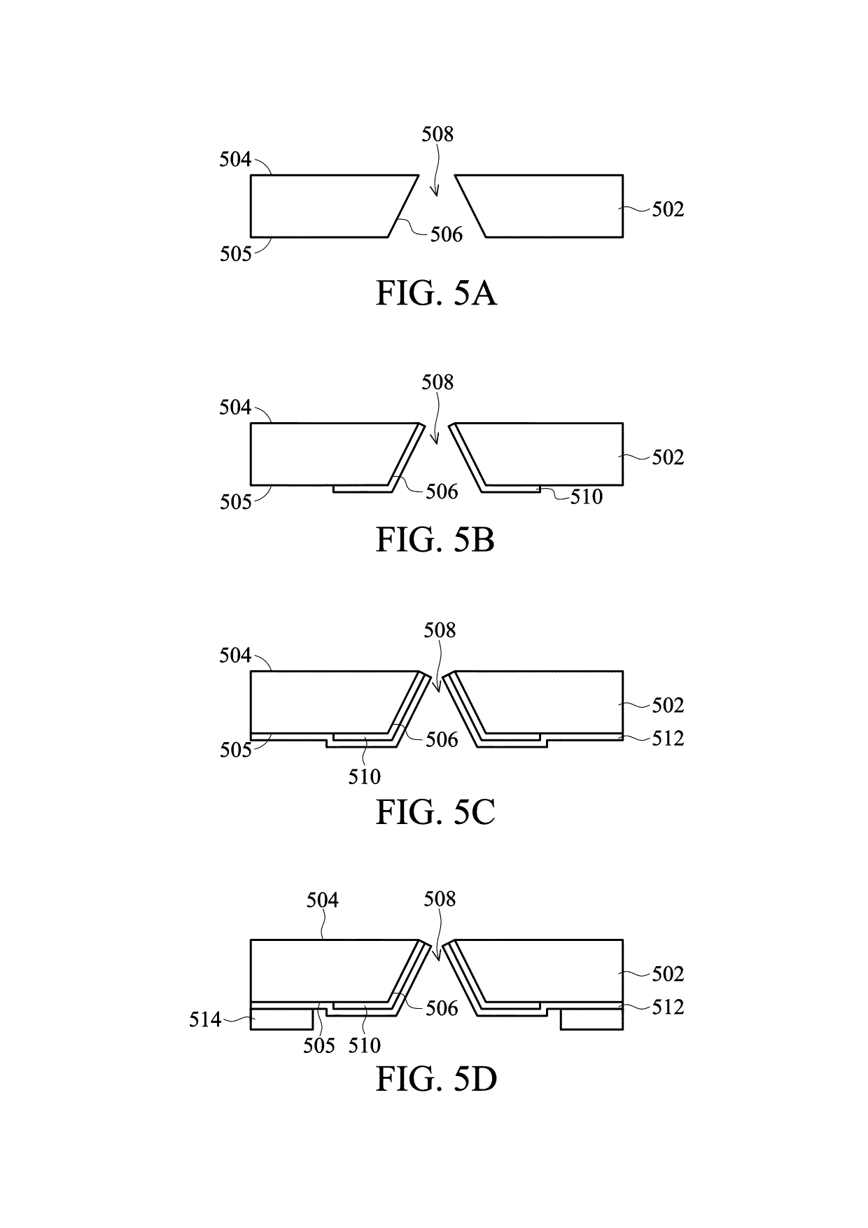

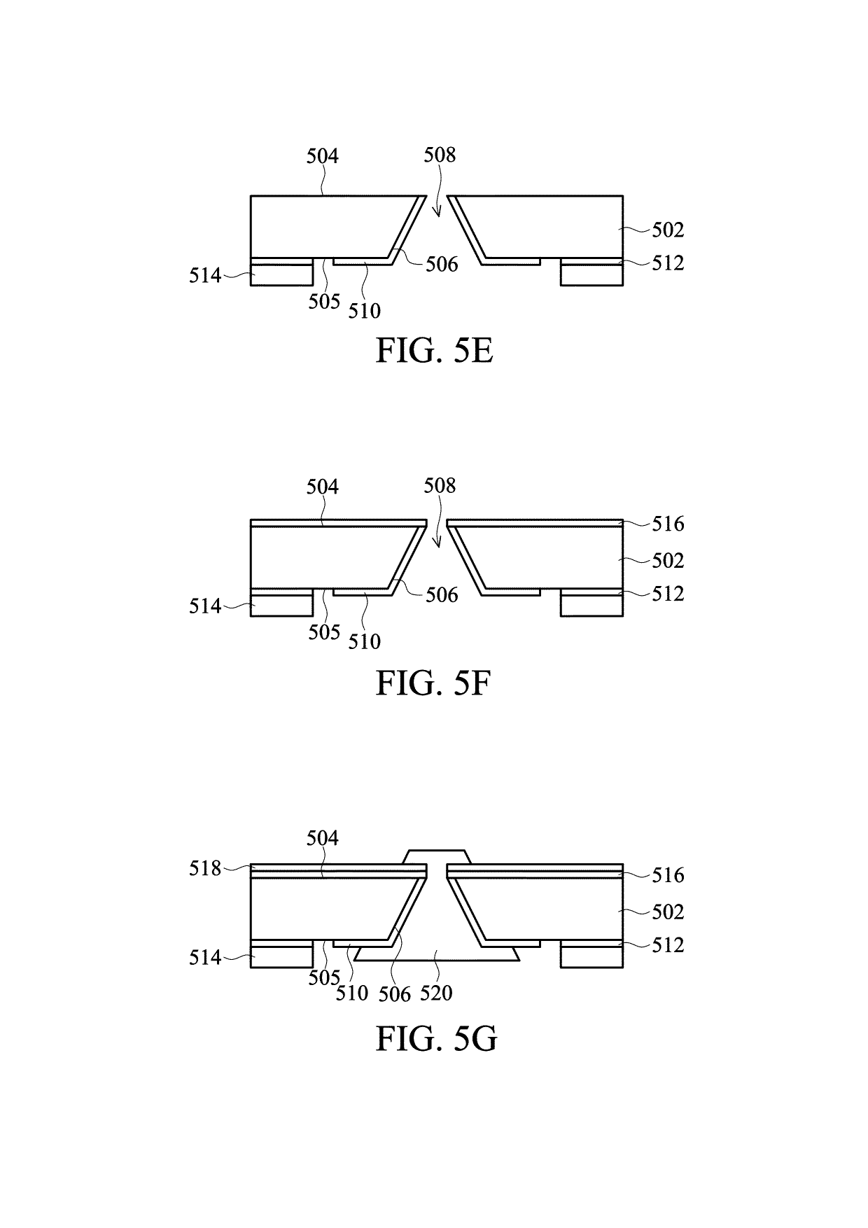

A method for forming a metal wrap-through back contact electrode solar cell with double side hetero junctions is illustrated with FIG. 5A˜FIG. 5G. Referring to FIG. 5A, a substrate 502 comprising a first surface 504 and a second surface 505 is provided. The substrate 502 can be formed with single crystalline silicon, or multi-crystalline silicon or other suitable semiconductor materials. Next, a drilling step is performed to the substrate 502 to form a through hole 508 in the substrate 502. Note that the surface in the through hole 508 is referred to as a third surface 506 in the following paragraph. In an embodiment of the invention, the substrate 502 is a first type semiconductor, such as an n type. Referring to FIG. 5B, an insulating layer 510 is formed on the second surface 505 of the substrate 502 and the third surface 506 in the through hole 508. In an embodiment of the invention, the insulating layer 510 comprises silicon nitride. Referring to FIG. 5C, a first thin film semiconductor layer is formed on the second surface 505 of the substrate 502 and extended to be over the insulator layer 510 in the through hole 508. In general, the thin film semiconductor layer comprises amorphous silicon, nanocrystalline silicon, microcrystalline silicon, microcrystalline silicon carbonate, amorphous silicon germanium, nanocrystalline silicon germanium, microcrystalline silicon germanium, amorphous germanium, nanocrystalline germanium, or microcrystalline germanium. In an embodiment of the invention, the thin film semiconductor layer is an amorphous silicon layer. In an embodiment of the invention, the first thin film semiconductor layer 512 is a first type amorphous silicon layer, such as an n type. An intrinsic thin film semiconductor layer (not shown) can be disposed between the first thin film semiconductor layer 512 and the substrate 502. Next, referring to FIG. 5D, a patterned metal layer 514 is formed on a first thin film semiconductor layer 512 on the second surface 505 of the substrate 502 by, for example, a screen printing process. In an embodiment of the invention, the patterned metal layer 514 is formed of metal with a high conductive coefficient, such as aluminum or silver. Referring to FIG. 5E, a chemical etching process is performed using the patterned metal layer 514 as a mask to remove the first thin film semiconductor layer 512 not covered by the first patterned metal layer 514. Referring to FIG. 5F, a second thin film semiconductor layer 516 is formed on the first surface 504 of the substrate 502 to act as an emitter. In an embodiment of the invention, the second thin film semiconductor layer 516 is a second-type amorphous silicon layer, such as p type. An intrinsic thin film semiconductor layer (not shown) can be inserted between the second thin film semiconductor layer 516 and the substrate 502. Referring to FIG. 5G, a transparent conductive layer 518 is formed on the second thin film semiconductor layer 516. In an embodiment of the invention, the transparent conductive layer 518 comprises indium tin oxide (ITO). Next, a through hole connection layer 520 is formed, for example, by a screen printing process, to electrically connect the patterned metal layer 514 over the first surface 504 and the second surface 505 of the substrate 502 for directing the bus bar on the front side of the substrate 502 to the back side. A transparent conductive layer (not shown) can be inserted between the first thin film semiconductor layer 512 and the patterned metal layer 514. It is noted that since the exposed n type first thin film semiconductor layer 512 on the second surface 505 of the substrate 502 has been removed, a laser cutting process is not required.

According to the description above, a metal wrap-through back contact electrode solar cell with double side hetero junctions comprises the following elements. A substrate 502 comprising a first surface 504 and a second surface 505 is provided, wherein the substrate 502 is of a first type. A through hole 508 passes through the substrate 502, wherein the through hole 508 in the substrate 502 comprises a third surface 506. An insulating layer 510 is disposed on the third surface 506 in the through hole 508 and extended to be over the second surface 505 of the substrate 502. A second thin film semiconductor layer 516 is disposed on the second surface 505 of the substrate 502. A patterned metal layer 514 is disposed on the second thin film semiconductor layer 516, wherein the second thin film semiconductor layer 516 is not present out of the patterned metal layer 514 on the second surface 505 of the substrate 502. A second thin film semiconductor layer 516 is disposed on the first surface 504 of the substrate 502. A transparent conductive layer 518 is disposed on the second thin film semiconductor layer 516. A through hole connection layer 520 is disposed in the through hole 508 and extended to be over the first surface 504 and the second surface 505 of the substrate 502.

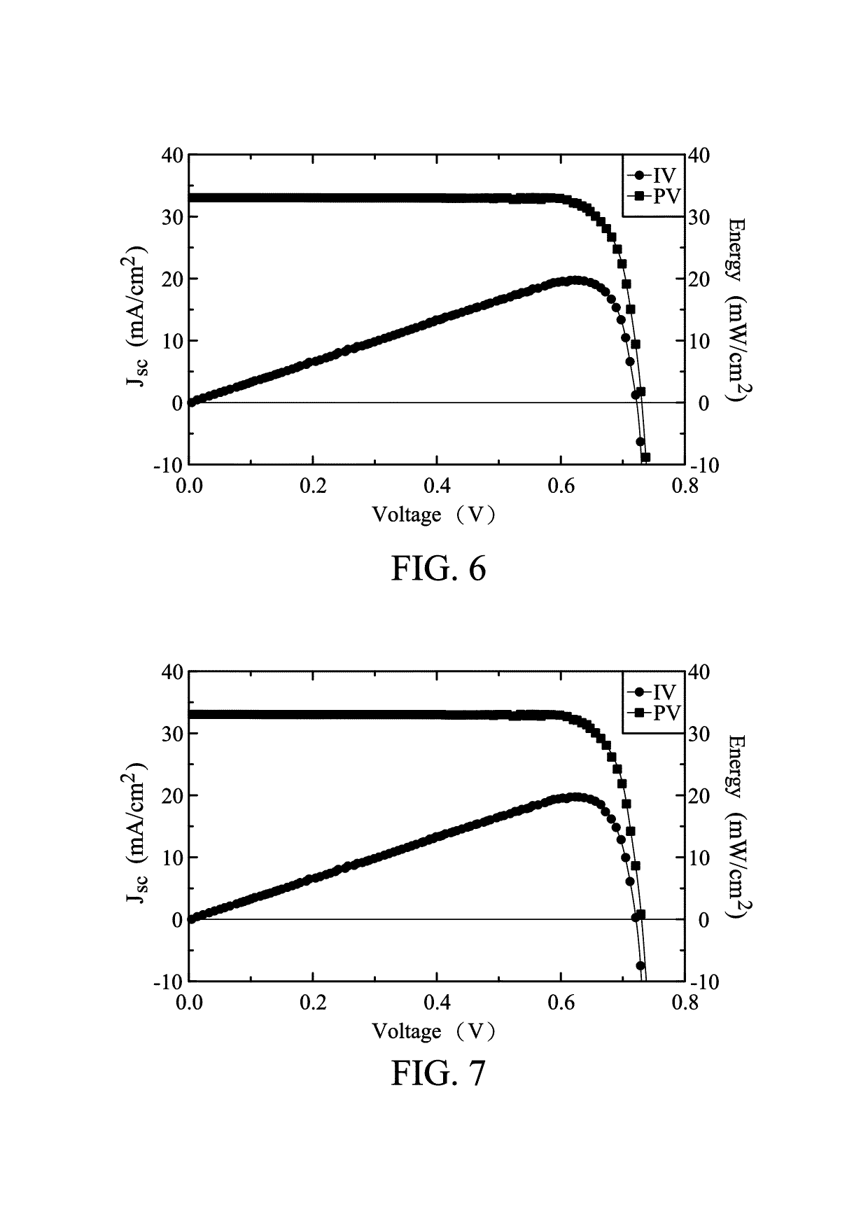

FIG. 6 shows short current (Jsc) and power as a function of voltage of a metal wrap-through back contact electrode solar cell with double side hetero junctions of the example shown in FIG. 2J (referred to first example). Referring to FIG. 6 and the Table 1 below, the short circuit of the solar cell of the first example is 32.98 mA/cm². The amorphous silicon layer having a reverse type with the substrate of the solar cell of the first example can provide good isolation and prevent shorts. In addition, as shown in the Table 1, the solar cell of the first example has larger efficiency as much as 0.6% than that of a standard hetero junction solar cell.

FIG. 7 shows short current (Jsc) and power as a function of voltage of a metal wrap-through back contact electrode solar cell with double side hetero junctions of the example shown in FIG. 4F (referred to second example). Referring to FIG. 7 and the Table 1 below, the short circuit of the solar cell of the second example is 32.97 mA/cm². The insulating layer in the through hole of the solar cell of the second example can provide good isolation and prevent shorts. In addition, as shown in the Table 1, the solar cell of the second example has an increased 0.5% efficiency when compared to that of a standard hetero junction solar cell.

TABLE 1

| | open circuit | Short | |
|---|---|---|---|
| | voltage | current | Efficiency |
| | (Voc) | (Jsc) | (Eff) |
| Standard hetero junction | 0.720 | 32.07 | 19.25 |
| solar cell | | | |
| First example | 0.721 | 32.98 | 19.84 |
| Second example | 0.720 | 32.97 | 19.78 |

The metal wrap-through back contact electrode solar cell with double side hetero junctions has advantages as follows. First, the metal wrap-through solar cells of an embodiment of the invention uses through holes in chips to direct bus bars at the front side to the back side to increase the light illumination area. This technique is applied to hetero junction solar cells to increase cell efficiency in the invention. Second, the cell structures described can be fabricated using simple processes and can be applied to the advanced solar cell industry. The invention forms through holes prior to forming amorphous silicon layers. Therefore, the invention can perform a chemical treating process after forming the through holes and before forming the amorphous silicon layers for reducing defects formed by a drilling process and increasing cell efficiency.

While the invention has been described by way of example and in terms of the preferred embodiments, it is to be understood that the invention is not limited to the disclosed embodiments. It is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A solar cell, comprising:
a substrate comprising a first surface and a second surface, wherein the substrate is of a first type;
a through hole passing through the substrate, wherein the substrate comprises a third surface in the through hole;
an insulating layer on the third surface in the through hole and extended to be over the second surface of the substrate;
a first thin film semiconductor layer disposed on the first surface of the substrate, wherein the first thin film semiconductor layer is of a first type;
a transparent conductive layer on the first thin film semiconductor layer; and
a through hole connection layer disposed in the through hole and extended to be over the first surface and the second surface of the substrate.

2. The solar cell as claimed in claim 1, further comprising a doping region disposed below the second surface of the substrate and the third surface in the through hole, wherein the doping region is of a first type.

3. The solar cell as claimed in claim 1, further comprising a first patterned metal layer disposed on the transparent conductive layer and a second patterned metal layer disposed on the second surface of the substrate.

4. The solar cell as claimed in claim 1, further comprising an intrinsic thin film semiconductor layer between the first thin film semiconductor layer and the substrate.

5. The solar cell as claimed in claim 1, further comprising a second thin film semiconductor layer disposed on the second surface of the substrate and extends into the through hole, wherein the second thin film semiconductor layer is of a first type, and the solar cell further comprises an intrinsic thin film semiconductor layer between the second thin film semiconductor layer and the second surface of the substrate.

6. The solar cell as claimed in claim 1, further comprising a transparent metal layer disposed on the second thin film semiconductor layer, and the solar cell further comprises another transparent conductive layer between the second thin film semiconductor layer and a patterned metal layer.

7. The solar cell as claimed in claim 1, further comprising a second thin film semiconductor layer disposed on the second surface of the substrate, an intrinsic thin film semiconductor layer between the second thin film semiconductor layer and the second surface of the substrate, and another transparent conductive layer between the second thin film semiconductor layer and a patterned metal layer, wherein the second thin film semiconductor layer is not disposed out of the patterned metal layer on the second surface of the substrate.
